(19) United States
(12) Patent Application Publication
(10) Pub. No.: US 2009/0072281 A1
(43) Pub. Date: Mar. 19, 2009

(54) CMOS image sensor layout capable of removing difference between Gr and Gb sensitivities and method of laying out the CMOS image sensor

(76) Inventors: Bum-suk Kim, Seoul (KR); Kyoung-sik Moon, Hwaseong-si (KR); Yun-ho Jang, Seoul (KR); Sae-young Kim, Suwon-si (KR)

Correspondence Address: HARNESS, DICKEY & PIERCE, P.L.C., P.O. BOX 8910, RESTON, VA, 20195, US

(21) Appl. No.: 12/153,919

(22) Filed: May 28, 2008

(30) Foreign Application Priority Data
May 28, 2007 (KR) 10-2007-0051562

(51) Int. Cl. H01L 31/112; H01L 31/18

(52) U.S. Cl. 257/292; 438/70; 257/E31.079; 257/E31.127

(57) ABSTRACT

Provided is a layout of a CMOS image sensor having an asymmetrical pixel structure in which a plurality of photodiodes may share a transistor block. The layout may include a first region in which a plurality of photodiodes are arranged asymmetrically on a semiconductor substrate, a second region including a metal shield layer arranged on an upper surface of the first region, and a third region arranged on an upper surface of the second region. The metal shield layer may be arranged asymmetrically according to the layout of the photodiodes.

### PRIORITY STATEMENT

This application claims the benefit under 35 U.S.C. § 119 of Korean Patent Application No. 10-2007-0051562, filed on May 28, 2007, in the Korean Intellectual Property Office, the entire contents of which are incorporated herein by reference.

### BACKGROUND

1. Technical Field

Example embodiments are directed to a layout of a Complementary Metal Oxide Semiconductor (CMOS) image sensor, and a related method of the same. The layout may have an asymmetrical pixel structure in which a plurality of photodiodes share a transistor block, and may reduce and/or prevent generations of Gr/Gb sensitivity differences.

2. Description of the Related Art

FIG. 1A is a circuit diagram of a pixel 100 of a conventional CMOS image sensor. Referring to FIG. 1A, a pixel 100 includes a photodiode 101 and a plurality of transistors, namely, first, second, third, and fourth transistors M1, M2, M3, and M4.

The first transistor M1 may operate as a transfer transistor, the second transistor M2 may operate as a reset transistor, the third transistor M3 may operate as a source follower, and the fourth transistor M4 may operate as a select transistor.

FIG. 1B illustrates a layout of the pixel 100 of the conventional CMOS image sensor illustrated in FIG. 1A. Referring to FIG. 1B, the pixel 100 may be divided into a photodiode region 101 and a transistor region 120. The photodiode region 101 denotes a region where a photodiode (PD) illustrated in FIG. 1A is laid out, and the transistor region 120 denotes a region where the first through fourth transistors M1, M2, M3, and M4 are laid out. For example, one pixel includes four independent transistors.

However, the pixel having this structure occupies a large area of the entire CMOS image sensor. Thus, in devices such as high-pixel digital cameras, the overall size of an image sensor significantly increases as the number of pixels included therein increases.

In order to reduce the overall size of an image sensor, the size of each pixel must be reduced. However, this leads to another problem, that is, a decrease in the size of the photodiode region 101.

FIG. 1C illustrates a metal shield layer 152 applied to the conventional pixel 100. Referring to FIG. 1C, metal shield layers 152 may be applied not only to the pixel 100 of FIG. 1B, but also to all of the other pixels having the same structures. Since both the pixels 100 of FIG. 1B have the same structure, the metal shield layer 152 applied thereto have the same structures.

Generally, pixel sizes of CMOS image sensors are being reduced in order to be built in small-sized mobile apparatuses such as cellular phones. At the same time, small-sized mobile apparatuses are increasing the number of pixels to obtain high quality images, such as those obtained by conventional digital still cameras (DSCs).

However, when the size of the conventional pixel 100 decreases, the size of the photodiode region 101 accordingly decreases. The size reduction of the photodiode region 101 reduces the number of electrons saturated as well as the sensitivity of light. As a result, an output signal having a value equal to or greater than a desired and/or predetermined value may not be secured, a signal to noise ratio (SNR) may be decreased, and the image quality may be degraded.

In order to reduce and/or prevent this reduction of the electron saturation amount and sensitivity, the size of the photodiode region 101 may be increased. In order to achieve this, a layout in which the photodiode region 101 shares an area with a transistor region or active region in which transistors are included has been proposed. In this sharing layout, the structures of the pixels are not consistent with one another. Thus, when using metal shield layers 152 with identical structures, the pixels may generate different output signals.

The difference between output signals is more pronounced in case of slanting incident light. In particular, when a difference between output signals from Gr and Gb pixels within a Bayer pattern is generated due to the difference between the output signals of pixels, noise may be generated on an output image screen and the image quality may be deteriorated.

As described above, in the conventional pixel structure, the sensitivity and the electron saturation amount decrease when using independent pixels. A structure that overcomes this problem also may generate noise due to the difference between output signals generated from Gr and Gb pixels.

### SUMMARY

Example embodiments provide a layout of a CMOS image sensor which may eliminate or reduce a difference between output signals generated from Gr and Gb pixels.

Example embodiments also provide a method of laying out a CMOS image sensor, by which the difference between output signals generated from Gr and Gb pixels may be eliminated or reduced.

Example embodiments may provide a layout of a CMOS image sensor having an asymmetrical pixel structure in which a plurality of photodiodes share a transistor block, the layout including a first region in which a plurality of photodiodes are arranged asymmetrically on a semiconductor substrate, a second region on an upper surface of the first region and including a metal shield layer, and a third region on an upper surface of the second region and including a color filter and a microlens, wherein the metal shield layer may be arranged asymmetrically according to the layout of the photodiodes.

The metal shield layer may be arranged in a region where no photodiodes are arranged.

A location of the microlens may be adjusted by microlens shift control.

The microlens shift control may be experimental adjustment of the location of the microlens according to changes in the height of each pixel in an image sensor, the incidence angle of light, the structure of the microlenses, etc.

The layout of the CMOS image sensor may further include a first insulation layer arranged between the first region and the second region, and a second insulation layer arranged between the second region and the third region.

Example embodiments may also include a method of laying out a CMOS image sensor having an asymmetrical pixel structure in which a plurality of photodiodes share a transistor block, the method including the operations of arranging a plurality of photodiodes on a semiconductor substrate, arranging a metal shield layer, and arranging a color filter and a microlens.

The metal shield layer may be arranged asymmetrically according to the layout of the photodiodes.

### BRIEF DESCRIPTION OF THE DRAWINGS

The above and other features and advantages of example embodiments will become more apparent by reviewing the detailed description of example embodiments while referring to the attached drawings in which:

FIG. 1A is a circuit diagram of a pixel in a conventional CMOS image sensor;

FIG. 1B illustrates a layout of the pixel of the conventional CMOS image sensor illustrated in FIG. 1A;

FIG. 1C illustrates a metal shield layer applied to the conventional pixel;

FIG. 2A illustrates a Bayer pattern for use in example embodiments;

FIG. 2B is a circuit diagram showing a case where a single shared pixel is formed due to sharing of a transistor region by four pixels according to example embodiments;

FIG. 2C illustrates an example layout of the shared pixel structure illustrated in FIG. 2B;

FIG. 3A illustrates an example layout of a CMOS image sensor according to an example embodiment;

FIG. 3B is an example vertical cross-sectional view of the layout illustrated FIG. 3A;

FIG. 4A is an example graph showing Gr/Gb sensitivity differences generated from a conventional layout and a layout according to example embodiments; and

FIG. 4B illustrates an example image generated in a conventional layout having a Gr/Gb sensitivity difference.

### DETAILED DESCRIPTION OF EXAMPLE EMBODIMENTS

Various example embodiments will now be described more fully with reference to the accompanying drawings. However, specific structural and functional details disclosed herein are merely representative for purposes of describing example embodiments, and one skilled in the art will appreciate that example embodiments may be embodied in many alternate forms and should not be construed as limited to only the example embodiments set forth herein.

It should be understood that, although the terms first, second, etc. may be used herein to describe various elements, these elements should not be limited by these terms. These terms are only used to distinguish one element from another. For example, a first element could be termed a second element, and similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a similar fashion (e.g., “between” versus “directly between”, “adjacent” versus “directly adjacent”, etc.).

The terminology used herein is for the purpose of describing example embodiments only and is not intended to be limiting of the example embodiments. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments described below with respect to the drawings are provided so that this disclosure will be thorough, complete and fully convey the concept of example embodiments to those skilled in the art. In the drawings, like numbers refer to like elements throughout. Further, the thicknesses of layers and regions are exaggerated for clarity in the drawings. Hereinafter, example embodiments will be described in detail with reference to the attached drawings.

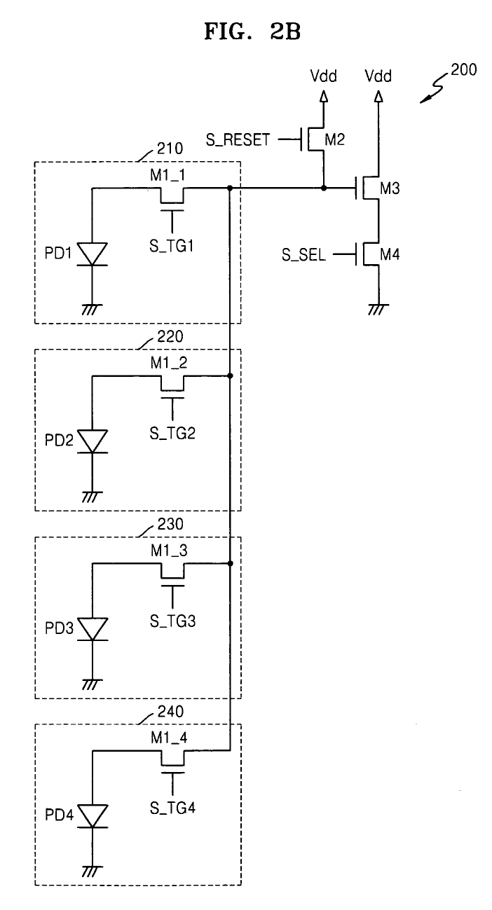

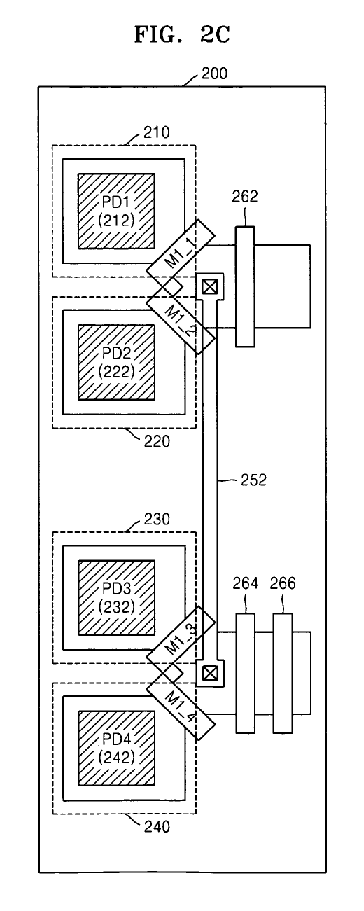

FIG. 2A illustrates a Bayer pattern for use in example embodiments.

Referring to FIG. 2A, the Bayer pattern may include a layer in which red (R) and green (Gr) colors are alternately arranged and a layer in which green (Gb) and blue (B) colors are alternately arranged.

FIG. 2B is a circuit diagram showing an example where a single shared pixel may be formed due to sharing of a transistor region by four pixels.

Example embodiments may be applied to shared CMOS image sensors (CISs) in which some of the transistors included therein are shared. In other words, four pixels included in a region 200 illustrated in FIG. 2A may be laid out in a single shared pixel structure.

Referring to FIG. 2B, four pixels 210, 220, 230, and 240 may share second, third, and fourth transistors M2, M3, and M4. For example, each pixel may include a photodiode PDi and a first transistor M1_i individually, and all of the pixels share the other transistors, namely, the second, third, and fourth transistors M2, M3, and M4.

By sharing the second, third, and fourth transistors M2, M3, and M4 in this way, a photodiode (PD) region may be increased without increasing the size of a pixel according to example embodiments.

FIG. 2C illustrates an example layout of the shared pixel structure of FIG. 2B. Referring to FIG. 2C, the shared pixel structure of FIG. 2B may include all of the R, Gr, Gb and B color pixels included in the region 200 of FIG. 2A. Thus, PD1, PD2, PD3, and PD4 may be photodiodes for collecting R, Gr, Gb and B color lights.

The second, third, and fourth transistors M2, M3, and M4 may be transistors 262, 264, and 266. A metal line 252 may be used as a node common to four pixels. The second, third, and fourth transistors M2, M3, and M4 may be laid out in various ways. Three gate polysilicon electrodes (GPs) 262, 264, and 266 are illustrated in FIG. 2C.

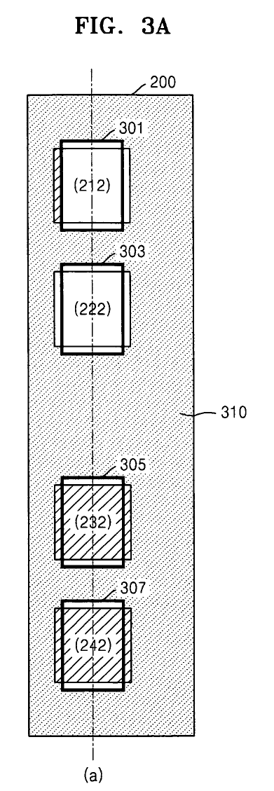

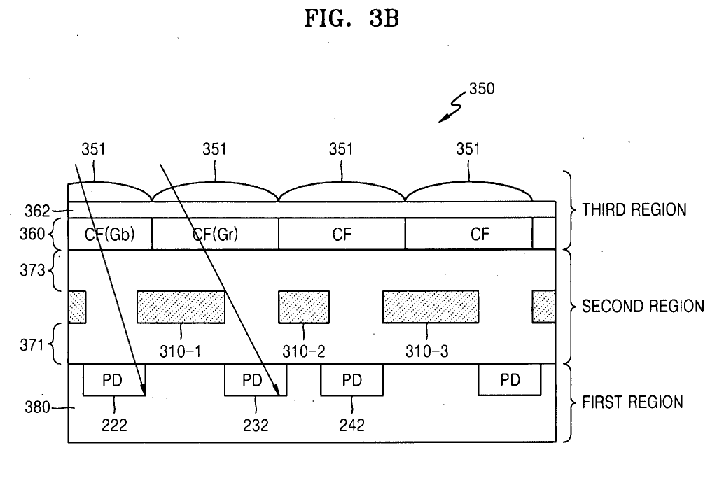

FIG. 3A illustrates a layout 200 of a CMOS image sensor according to an example embodiment.

Referring to FIG. 3A, the CMOS image sensor layout 200 may have a shared structure and may include an asymmetric metal shield layer 310.

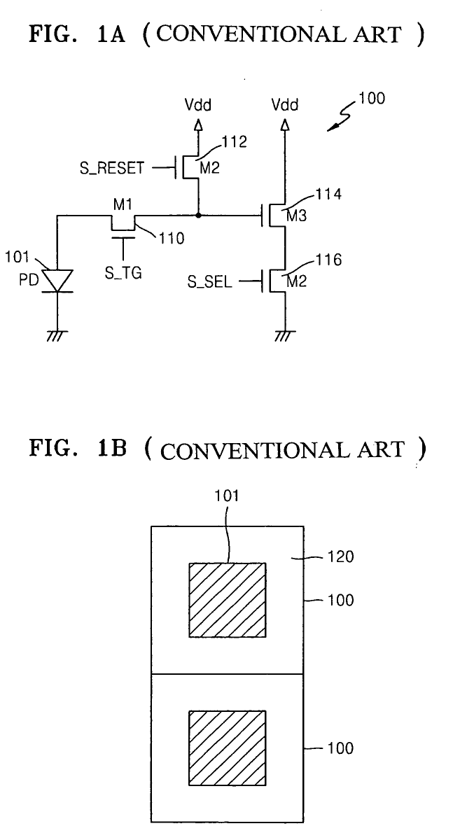

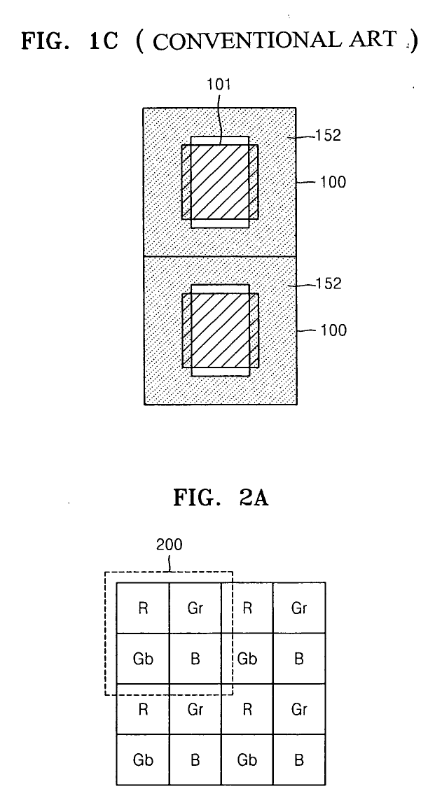

As illustrated in FIG. 2C, in the CMOS image sensor layout 200 having a shared structure, PD regions 212, 222, 232, and 242 are not arranged at identical locations on each pixel. The layout of FIG. 3A contrasts with the layout of FIG. 1B where PDs are arranged at identical locations on the respective pixels. The layout of FIG. 3A where the PDs 212, 222, 232, 242 are arranged in different locations is referred to as an asymmetrical layout.

Referring to FIG. 3A, the CMOS image sensor layout 200 according to the example embodiments may include the metal shield layer 310 which has an asymmetrical layout.

The metal shield layer 310 may be laid out according to the asymmetrical layout of PDs. In other words, according to the positions of the PDs, the positions of apertures vary. Apertures 301, 303, 305, and 307 may completely or partially overlap the PD regions 212, 222, 232, and 242. Alternatively, the apertures 301, 303, 305, and 307 may be laid out slightly apart from the PD regions 212, 222, 232, and 242 without overlapping.

In other words, when the PD region 212 is laid out as in FIG. 3A, the aperture 301 of the metal shield layer 310 is laid out as in FIG. 3A. FIG. 3B is a vertical cross-sectional view of the layout illustrated FIG. 3A. FIG. 3B illustrates a layer 350 obtained by vertically cutting the layout of FIG. 3A along line (a) illustrated in FIG. 3A.

Referring to FIG. 3B, the layout 350 may include a first region in which a plurality of PD regions 222, 232, and 242 are asymmetrically arranged on a semiconductor substrate 380, a second region in which metal shield layers 310-1, 310-2, and 310-3, a first insulation layer 371, and a second insulation layer 373 are included, and a third region in which a color filter 360 and microlenses 351 are included. The third region may further include an insulation layer 362 between the color filter 360 and the microlenses 351.

The metal shield layers 310-1, 310-2, and 310-3 may be arranged according to the layout of the PD regions 222, 232, and 242. For example, as an interval between the PD region 222 and the PD region 232 is large, the metal shield layer 310-1 is laid out to have a large width. As another example, as an interval between the PD region 232 and the PD region 242 is small, the metal shield layer 310-2 is laid out to have a small width.

The locations of the microlenses 351 may be adjusted by microlens shift control. The microlens shift control denotes an operation of experimentally adjusting the locations of the microlenses according to changes in the height of each pixel in an image sensor, the incidence angle of light, the structure of the microlenses, etc. An experiment for determining improving or optimizing locations may be conducted while horizontally shifting the microlenses 351 under each process condition.

A location of each microlens 351 that allows the highest amount of light collected by photodiodes from among the amounts of light collected by the photodiodes under different conditions such as the height of each pixel in an image sensor, the incidence angle of light, the structure of the microlenses (e.g., the configuration of photodiodes, a metal shield layer, or the like), etc. is selected as the optimal location of each microlens 351. Here, the highest amount of light means the highest output signal. A location at which the photodiodes output the maximum value from among all the locations to which each microlens 351 moves is referred to as an optimal location for each microlens 351. This optimization varies according to the aforementioned different process conditions, may be determined experimentally, and is not limited.

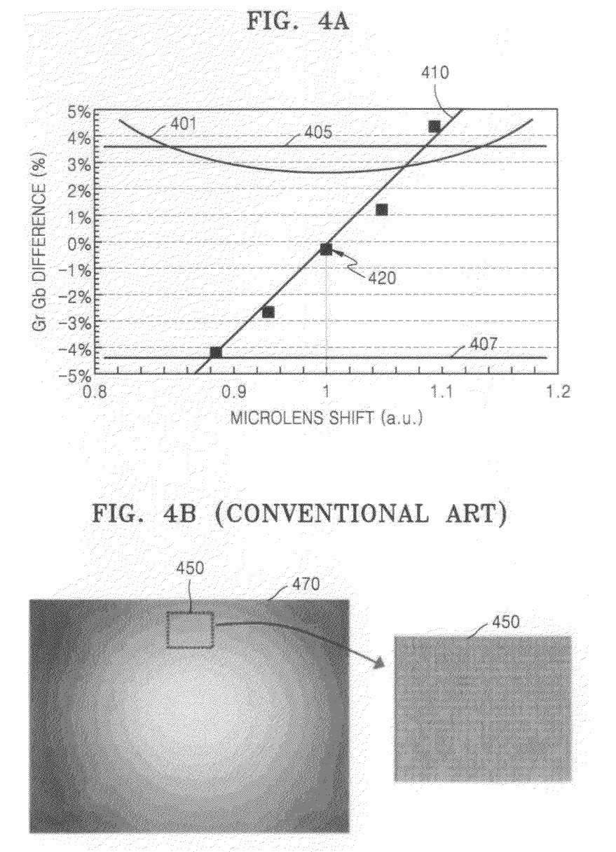

FIG. 4A is a graph showing Gr/Gb sensitivity differences generated from a conventional layout and a layout according to example embodiments.

A line 410 is a graph showing Gr/Gb sensitivity differences generated in a layout according to example embodiments, and lines 401, 405, and 407 show Gr/Gb sensitivity differences generated in a conventional shared pixel structure (not shown in the drawings) in which metal shield layers are symmetrically arranged. The y-axis represents a sensitivity difference between Gr and Gb colors (e.g., a difference between output signals), and the x-axis represents optimization that depends on microlens shift control. When the value of the x-axis is 1, the highest output signal is output. The sensitivity difference between Gr and Gr colors may be calculated using Equation 1:

$$\frac{\vert Gr - Gb \vert}{< G >} \times 100 \qquad ( 1 )$$

wherein G indicates an average of the values of Gr and Gb output signals, Gr indicates the output value of the Gr color, and Gb indicates the output value of the Gb color. The unit of a value obtained by Equation 1 is %.

Referring to FIG. 4A, when metal shield layers are arranged asymmetrically according to example embodiments and the microlens shift control is used, a point 420 where the sensitivity difference between Gr and Gb colors is 0 is generated. The difference between the output signals generated by the Gr and Gb colors may be controlled to be 0 according to example embodiments.

On the contrary, in a conventional shared pixel structure (not shown in the drawings) where metal shield layers are symmetrically arranged, no points where the sensitivity difference between Gr and Gb colors is 0 may be detected even when the microlens shift control is used. In other words, in the conventional pixel structure, sensitivity differences between the Gr/Gb colors are generated even when improvement or optimization of lens locations using the microlens shift control is performed.

FIG. 4B illustrates an image 470 generated in a conventional layout having a Gr/Gb sensitivity difference.

Referring to FIG. 4B, when a part 450 of the image 470 is magnified, a lattice pattern may be seen. In other words, when a sensitivity difference between Gr and Gb colors is generated, a lattice pattern appears on a part of the image 470 that is to be displayed flat. This lattice represents noise. The greater the sensitivity difference between Gr and Gb colors, the more pronounced the lattice.

In a layout according to example embodiments, sensitivity differences between Gr and Gb colors are reduced or eliminated, and thus noise such as the lattice illustrated in FIG. 4B may be reduced and/or prevented. In addition, by arranging metal shield layers according to an asymmetrical photodiode layout and adjusting the locations of microlenses according to microlens shift control, the sizes of output signals generated from small-sized photodiodes may not be reduced.

A CMOS image sensor laying-out method according to an example embodiment has the same technical spirit as the above-described CMOS image sensor according to previously described example embodiments. Hence, the CMOS image sensor laying-out method will be understood by those of ordinary skill in the art with reference to the above description, so a detailed description thereof is omitted.

As described above, a CMOS image sensor layout according to example embodiments may reduce and/or prevent Gr/Gb sensitivity differences from being generated in image sensors having small-sized pixels.

As described above, a CMOS image sensor laying-out method according to example embodiments may reduce and/or prevent Gr/Gb sensitivity differences from being generated in image sensors having small-sized pixels.

While example embodiments have been particularly shown and described with reference to the drawings, it will be understood by those of ordinary skill in the art that various changes in form and details may be made therein without departing from the spirit and scope of this disclosure.

What is claimed is:

1. A CMOS image sensor layout comprising:
a first region in which a plurality of photodiodes are arranged asymmetrically on a semiconductor substrate;
a second region arranged on the first region and including a metal shield layer arranged asymmetrically with respect to the plurality of photodiodes; and
a third region arranged on the second region and including a color filter and a microlens.

2. The CMOS image sensor layout of claim 1, wherein the second region is on an upper surface of the first region, and the third region is on an upper surface of the second region.

3. The CMOS image sensor layout of claim 1, wherein the metal shield layer is arranged in a region where no photodiodes are arranged.

4. The CMOS image sensor layout of claim 3, wherein the photodiodes are in a photodiode region; and
the metal shield layer reduces incidence of light upon a region other than the photodiodes so that light incident via the microlens is passed to only the photodiode region.

5. The CMOS image sensor layout of claim 4, wherein an aperture of the metal shield layer in the second region is filled with an insulation layer.

6. The CMOS image sensor layout of claim 1, wherein a location of the microlens is adjusted by microlens shift control.

7. The CMOS image sensor layout of claim 6, wherein the microlens shift control is an adjustment of the location of the microlens based on at least one of changes in the height of each pixel in an image sensor, the incidence angle of light, and the structure of the microlenses.

8. The CMOS image sensor layout of claim 1, further comprising:
a first insulation layer between the first region and the second region; and
a second insulation layer between the second region and the third region.

9. The CMOS image sensor layout of claim 8, wherein the third region comprises:
a planarization layer between the color filter and the microlens.

10. The CMOS image sensor layout of claim 1, wherein the plurality of photodiodes share a transistor block; and
the metal shield layer is asymmetrically arranged between the plurality of photodiodes such that apertures are created which correspond to locations of the plurality of photodiodes.

11. The CMOS image sensor layout of claim 10, wherein the metal shield layer is in a region above the photodiodes such that no photodiodes are arranged in the semiconductor substrate below the metal shield layer.

12. The CMOS image sensor layout of claim 10, wherein the apertures completely or partially overlap the plurality of photodiodes.

13. The CMOS image sensor layout of claim 10, wherein the apertures are offset from the plurality of photodiodes without overlapping the plurality of photodiodes.

14. A method of laying out a CMOS image sensor comprising:
asymmetrically arranging a plurality of photodiodes on a semiconductor substrate;
asymmetrically arranging a metal shield layer with respect to the arrangement of the plurality of photodiodes; and
arranging a color filter and a microlens on the metal shield layer.

15. The method of claim 14, wherein asymmetrically arranging the metal shield layer includes arranging the metal shield layer in a region where no photodiodes are arranged.

16. The method of claim 15, wherein asymmetrically arranging the metal shield layer comprises:
arranging a first insulation layer between a region where the plurality of photodiodes are arranged and a region where the metal shield layer is arranged; and
arranging a second insulation layer between the region where the metal shield layer is arranged and a region where the color filter is arranged.

17. The method of claim 14, wherein arranging the microlens includes arranging the microlens at a location determined by microlens shift control.

18. The method of claim 17, further comprising:
adjusting a location of the microlens according to changes in at least one of the height of each pixel in an image sensor, the incidence angle of light, and the structure of the microlenses.

19. The method of claim 14, wherein arranging the color filter and the microlens comprises:
arranging the color filter;
arranging a planarization layer on the color filter; and
arranging the microlens on the planarization layer.
